(19) United States
(12) Patent Application Publication
(10) Pub. No.: US 2025/0046684 A1
(43) Pub. Date: Feb. 6, 2025

(54) Converter Package with Integrated Inductor

(71) Applicant: Texas Instruments Incorporated, Dallas, TX (US)

(72) Inventors: Makoto Shibuya, Tokyo (JP); Yasmine Yan, San Jose, CA (US); Masamitsu Matsuura, Beppu-shi (JP); Anindya Poddar, Sunnyvale, CA (US)

(21) Appl. No.: 18/362,936

(22) Filed: Jul. 31, 2023

(51) Int. Cl. H01L 23/495; H05K 1/18

(52) U.S. Cl. CPC H01L 23/49555; H01L 23/4951; H05K 1/181; H01L 23/3107; H05K 2201/1003; H05K 2201/10515; H05K 2201/1053

(57) ABSTRACT

A semiconductor package comprises an integrated circuit die covered by a mold compound to form a four-sided package with a top surface and a bottom surface. A first group of no-lead contacts are exposed on a first side and on the bottom surface of the package. A second group of no-lead contacts are exposed on a second side and on the bottom surface of the package, wherein the second side is opposite the first side. A first external lead extends from a third side of the package. A second external lead extends from a fourth side of the package opposite the third side. The first and second external leads bent to extend above the top surface of the package. The first and second external leads have a gull-wing shape or a J-shape.

### BACKGROUND

Semiconductor devices integrated circuits are getting smaller, semiconductor packages are getting smaller, and systems are getting smaller. Along with this, the density of component mounting on System PCB is increasing, and space-saving designs are needed.

### SUMMARY

In one arrangement, a semiconductor package comprises an integrated circuit (IC) die covered by a mold compound to form a four-sided package with a top surface and a bottom surface. A first group of no-lead contacts are exposed on a first side and on the bottom surface of the package. A second group of no-lead contacts are exposed on a second side and on the bottom surface of the package, wherein the second side is opposite the first side. A first external lead extends from a third side of the package. A second external lead extends from a fourth side of the package opposite the third side. The first and second external leads bent to extend above the top surface of the package.

The first and second external leads can be shaped as gull-wing leads each having a top end that bends away from the package. Alternatively, the first and second external leads can be J-shape leads each having a top end that bends over the top surface of the package. An opening can be formed in one or more of the first and second external leads.

The first external lead and one or more of the first group of no-lead contacts are part of a continuous leadframe segment that is attached to the IC die.

The second external lead comprises a half etched end portion within the mold compound. The end portion has half etched tabs that extend laterally from the second external lead. The tabs are not exposed on the bottom surface of the package. The second external lead is not directly electrically coupled to the IC die.

Each of the no-lead contacts comprise half etched portions that are not exposed through the mold compound on the bottom surface of the package.

In another arrangement, a semiconductor package comprises a semiconductor die electrically coupled to one or more leadframe segments, and an encapsulant covers the semiconductor die and at least a portion of the leadframe segments. The leadframe segments form a first set of no-lead contacts along a first bottom edge of the package. The leadframe segments also form a first external lead on a second bottom edge of the package. A second external lead is formed on a third bottom edge of the package opposite the second edge. The first and second external leads extend above a top surface of the encapsulant. A second set of no-lead contacts are positioned along a fourth bottom edge of the package opposite the first edge.

The first and second external leads are shaped as gull-wing leads or as J-shape leads. The gull-wing leads each have a top end that bends away from the package. The J-shape leads each have a top end that bends over the top surface of the encapsulant. An opening is formed in one or more of the first and second external leads. The first external lead is electrically coupled to one or more of the first set of no-lead contacts. The first external lead and one or more of the first set of no-lead contacts are part of a continuous leadframe segment.

The second external lead is not directly electrically coupled to semiconductor die. The second external lead comprises a half etched end portion within the encapsulant. The end portion has two half etched tabs extending laterally from the second external lead. The tabs are not exposed on a bottom surface of the package.

The first set of no-lead contacts comprise half etched portions that are not exposed through the encapsulant on a bottom surface of the package.

An electrical device, such as an inductor, capacitor, or other passive component, is attached to the top ends of the first and second external leads above the top surface of the encapsulant.

### BRIEF DESCRIPTION OF THE DRAWINGS

Having thus described the invention in general terms, reference will now be made to the accompanying drawings, wherein:

FIGS. 1A and 1B are top and bottom isometric views of an electronic system, such as a direct current power converter.

FIG. 2 is a side view of an electronic system having a semiconductor package with gull-wing leads mounted on the top surface of a printed circuit board.

FIG. 3 is a side view of an electronic system having an alternate semiconductor package with J-leads.

FIG. 4A is an isometric view showing how the leadframe portion of a semiconductor package is attached to a semiconductor die and encapsulated in mold compound.

FIG. 4B is a top cross-section view of semiconductor package in FIG. 4A.

FIG. 5A illustrates a leadframe strip showing an example arrangement of leads for use with a hybrid package as described herein.

FIG. 5B is a detailed view of a portion of the leadframe strip shown in FIG. 5A illustrating how an IC die is positioned relative to the leadframe elements.

FIG. 6 shows portions of the leadframe sheet of FIG. 5A with contact segments that are half-etched on the bottom side.

FIG. 7 is a bottom isometric view of a semiconductor package that has been assembled using a leadframe sheet as illustrated in FIG. 6.

FIG. 8 shows a top isometric view of a semiconductor package having end leads with an alternative configuration.

### DETAILED DESCRIPTION

The present disclosure is described with reference to the attached figures. The figures are not drawn to scale, and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

Corresponding numerals and symbols in the different figures generally refer to corresponding parts, unless otherwise indicated. The figures are not necessarily drawn to scale. In the drawings, like reference numerals refer to like elements throughout, and the various features are not necessarily drawn to scale. In the following discussion and in the claims, the terms “including,” “includes,” “having,” “has,” “with,” or variants thereof are intended to be inclusive in a manner similar to the term “comprising,” and thus should be interpreted to mean “including, but not limited to . . . ” Also, the terms “coupled,” “couple,” and/or or “couples” is/are intended to include indirect or direct electrical or mechanical connection or combinations thereof. For example, if a first device couples to or is electrically coupled with a second device that connection may be through a direct electrical connection, or through an indirect electrical connection via one or more intervening devices and/or connections. Elements that are electrically connected with intervening wires or other conductors are considered to be coupled. Terms such as “top,” “bottom,” “front,” “back,” “over,” “above,” “under,” “below,” and such, may be used in this disclosure. These terms should not be construed as limiting the position or orientation of a structure or element but should be used to provide spatial relationship between structures or elements.

The term “semiconductor die” is used herein. A semiconductor die refers to a thin slice of material, such as crystalline silicon, that is used to fabricate integrated circuits. A large number of integrated circuits may be created on an active surface of the semiconductor die. Discrete semiconductor devices can be integrated circuits with hundreds or thousands of transistors coupled to form a functional circuit, for example a microprocessor or memory device. The semiconductor device may also be referred to herein as a semiconductor wafer or an integrated circuit (IC) die.

The term “semiconductor package” is used herein. A semiconductor package has at least one semiconductor die electrically coupled to terminals and has a package body that protects and covers the semiconductor die. In some arrangements, multiple semiconductor dies can be packaged together. For example, a power metal oxide semiconductor (MOS) field effect transistor (FET) semiconductor device and a second semiconductor device (such as a gate driver die, or a controller die) can be packaged together to form a single packaged electronic device. Additional components such as passive components, such as capacitors, resistors, and inductors or coils, can be included in the packaged electronic device. The semiconductor die is mounted with a package substrate that provides conductive leads. A portion of the conductive leads form the terminals for the packaged device. In wire bonded integrated circuit packages, bond wires couple conductive leads of a package substrate to bond pads on the semiconductor die. The semiconductor die can be mounted to the package substrate with a device side surface facing away from the substrate and a backside surface facing and mounted to a die pad of the package substrate. The semiconductor package can have a package body formed by a thermoset epoxy resin mold compound in a molding process, or by the use of epoxy, plastics, or resins that are liquid at room temperature and are subsequently cured. The package body may provide a hermetic package for the packaged device. The package body may be formed in a mold using an encapsulation process, however, a portion of the leads of the package substrate are not covered during encapsulation, these exposed lead portions form the terminals for the semiconductor package. The semiconductor package may also be referred to as a “integrated circuit package,” a “microelectronic device package,” or a “semiconductor device package.”

The term “external lead” is used herein. In packaged integrated circuits, external leads provide an electrical connection from contacts or pads on the exterior of a semiconductor package to an internal leadframe that is coupled to a semiconductor die within the package. The external lead is a portion of the leadframe that is exposed outside of a mold compound or other protective encapsulant for the semiconductor package. The leadframe and the external leads may be etched, stamped, or cut to have a desired cross-section shape.

The terms “gull wing” and “J-lead” are used herein to describe the shape of external leads. As used herein, “gull-wing shape” refers to a pair of external leads wherein each lead has an end that is attached to a semiconductor package and a free end. The free ends of each pair of gull-wing leads bend away from each other and from the semiconductor package. As used herein, “J-shape” refers to a pair of external leads wherein each lead has an end that is attached to the semiconductor package and a free end. The free ends of each pair of J-shaped leads bend toward each other. The free ends of each pair of J-shaped leads extend toward or over the semiconductor package.

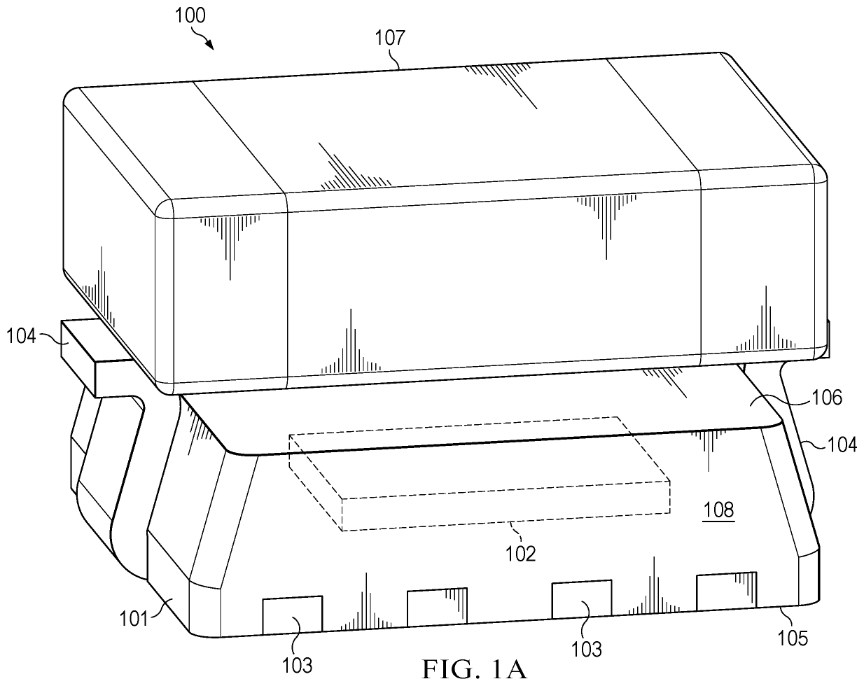

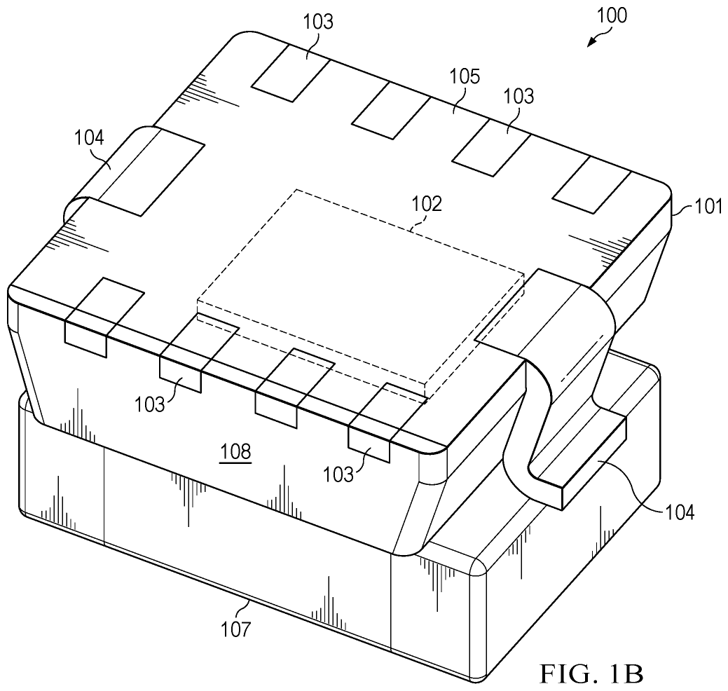

FIGS. 1A and 1B are top and bottom isometric views of an electronic system, such as a direct current (DC)-DC power converter, generally designated 100. A semiconductor package 101 includes a power control integrated circuit (IC) 102. Leadframe segments (not shown) inside semiconductor package 101 couple the power control IC 102 to a number of external contacts 103, 104. No-lead contacts 103, such as the leads found on quad-flat no-lead (QFN) and dual-flat no-lead (DFN) devices, allow for surface mount of the semiconductor package 101 directly onto a printed circuit board (PCB). Gull-wing leads 104 allow for mounting other devices onto semiconductor package 101. Gull-wing leads 104 have portions that extend upward from a bottom surface 105 of semiconductor package 101 and reach above top surface 106 of semiconductor package 101. Gull-wing leads 104 are electrically coupled to a passive component 107, such as an inductor. In other arrangements, passive component 107 may be a capacitor, resister, coil, or the like. Semiconductor package 101 includes an encapsulant or mold compound 108 that covers and protects IC 102 and at least a portion of the leadframe segments.

Semiconductor package 101 is a quad-side pin-layout package with reverse gull-wing leads 104 on two sides. The gullwing leads 104 utilize capabilities of existing package designs, such as a small-outline IC (SOIC), a small-outline package (SOP), or a small-outline transistor (SOT). However, the reverse gull-wing leads extend in an opposite direction compared to a typical package design (i.e., gull-wing leads 104 extend upward instead of downward from bottom surface 105).

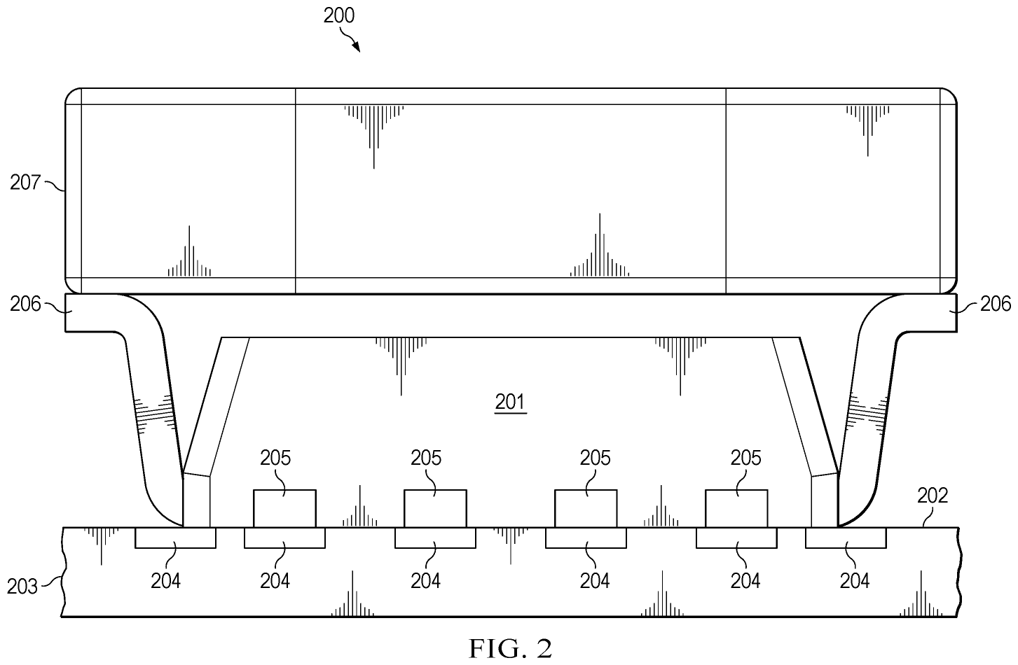

FIG. 2 is a side view of an electronic system generally designated 200 having a semiconductor package 201, such as a power control package, that is mounted on the top surface 202 of PCB 203. Solder paste is applied to pads 204 on surface 202 on PCB 203 using a stencil or screen. Semiconductor package 201 is placed on the pads 204. No-lead contacts 205 and gull-wing leads 206 are attached to the PCB pads 204 by reflow soldering. Semiconductor package 201 has a hybrid design with rows of no-lead contacts 205 located on opposite sides of the package and gull-wing leads 206 attached on opposite ends of the package. An inductor 207 or another passive component is attached to semiconductor package 201 at the upper end ends of gull-wing leads 206. Electronic system 200 has a smaller footprint than typical micro system-in-package (SiP) modules and utilizes existing assembly processes with changes to the lead design and layout.

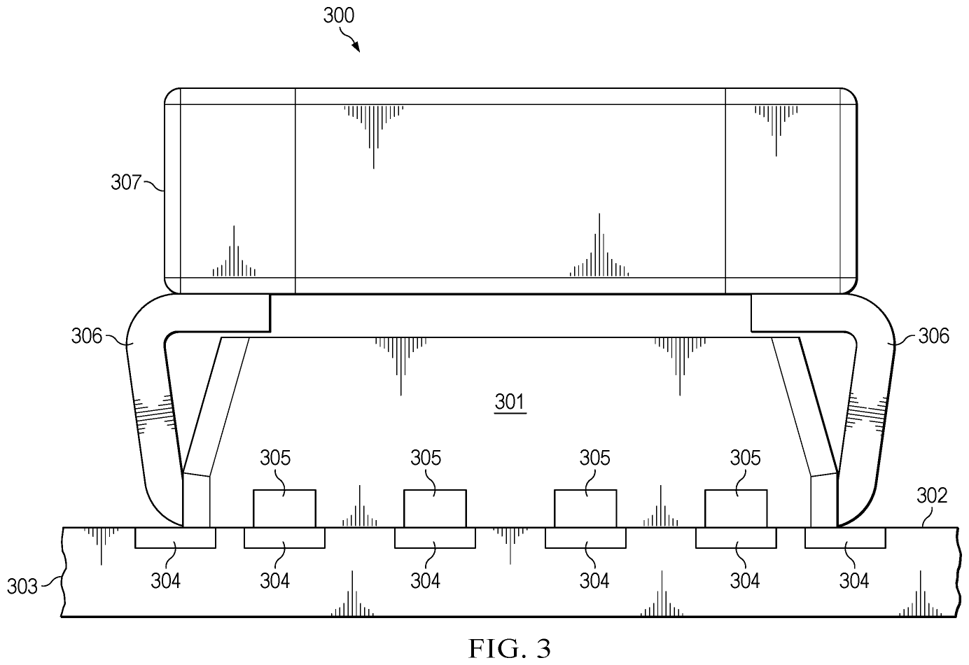

FIG. 3 is a side view of an electronic system generally designated 300 having an alternate hybrid semiconductor package 301. Like semiconductor package 201, semiconductor package 301 is mounted on a top surface 302 of a PCB 303. Semiconductor package 301 is placed surface 302, and no-lead contacts 305 and J-wing leads 306 are soldered to PCB pads 304. Semiconductor package 301 has an alternative hybrid design with rows of no-lead contacts 305 located on opposite sides of the package and J-wing leads 306 attached on opposite ends of the package. An inductor 307 or another passive component is attached to semiconductor package 301 at the upper end ends of J-wing leads 306.

Compared to the gull-wing leads 206 that bend outward in FIG. 2, the J-wing leads 306 fold over the top surface 308 of semiconductor package 301, which allows for attachment to a shorter inductor 307 compared to inductor 207 and for a narrower overall width of system 300. Additionally, electronic system 300 has a smaller footprint than typical micro SiP modules and utilizes existing assembly processes with changes to the lead design and layout.

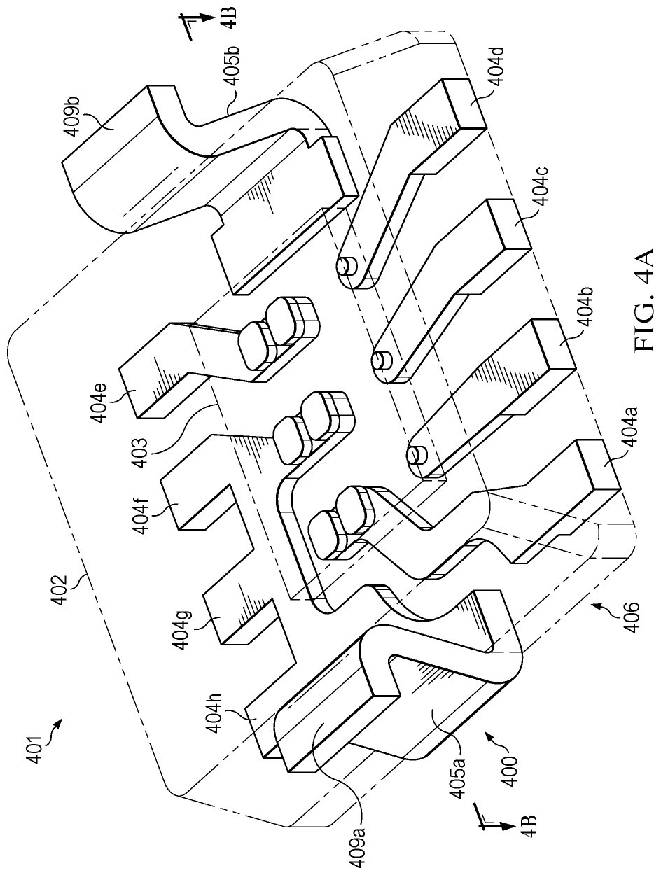

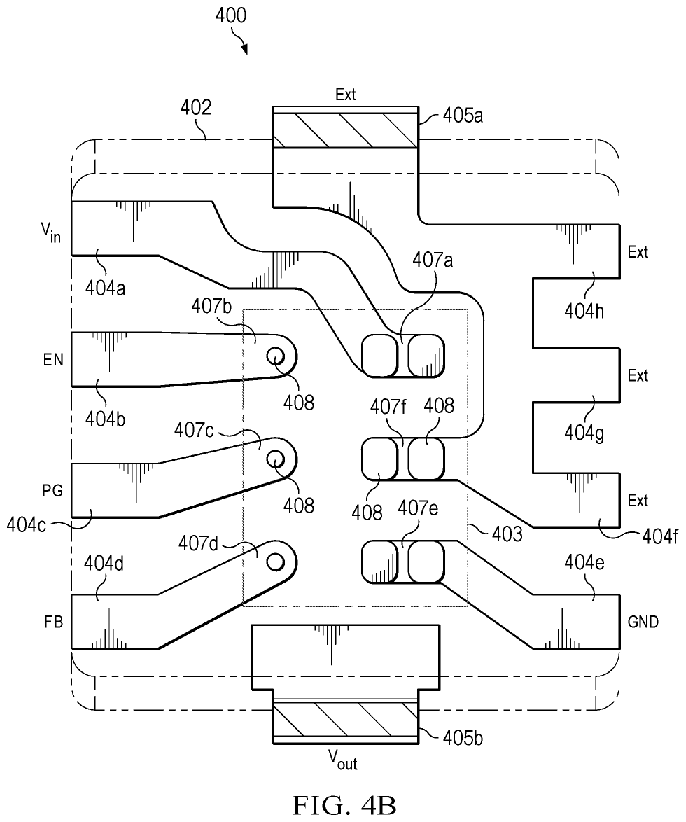

FIG. 4A is an isometric view showing the leadframe portion 400 of a semiconductor package 401 according to one arrangement. The mold compound 402 and IC die 403 in semiconductor package 401 are shown in phantom lines to illustrate their position relative to leadframe segment 400. IC die 403 is mounted flip chip on lead (FCOL) to leadframe segment 400. In another arrangement,

FIG. 4B is a top cross-section view of semiconductor package 401 in FIG. 4A showing mold compound 402 and IC die 403 in phantom lines relative to leadframe segment 400. The leadframe contacts in FIG. 4B are further annotated to identify example pin names. Leadframe segment 400 has a first set of no-lead contact regions 404a-d on one side of semiconductor package 401 and a second set of no-lead contact regions 404e-h on the opposite side. Gull-wing leads 405a,b are located on opposite ends of semiconductor package 401.

A bottom face of each no-lead contact 404a-h and each gull-wing lead 405a,b is exposed on the bottom surface 406 of semiconductor package 401. This allows for electrical connections to external circuits such as when semiconductor package 401 is mounted on a PCB surface.

Bond pads on IC die 403 are electrically connected to die mount contacts 407a-f on leadframe segment 400. One or more copper posts 408 are used to connect the die mount contacts 407a-f to IC die 403. Die mount contacts 407a-e are each individually tied electronically to a no-lead contact 404a-e on the side of semiconductor package 401. No-lead contact 404a is part of a leadframe trace that ends in die mount contact 407a. No-lead contact 404b is part of a leadframe trace that ends in die mount contact 407b. No-lead contact 404c is part of a leadframe trace that ends in die mount contact 407c. No-lead contact 404d is part of a leadframe trace that ends in die mount contact 407d. No-lead contact 404h is part of a leadframe trace that ends in die mount contact 407e.

The no-lead contacts 404e-g and gull-wing lead 405a are connected as part of a common leadframe trace with die mount contact 407f. The top portions 409a,b of gull-wing leads 405a,b flare outward away from semiconductor package 401 and are adapted for attachment of an external component, such as an inductor, capacitor, or other passive device. In an alternative arrangement, the gull-wing leads 405a,b may be replaced with J-leads that have a top portion bending inward and over the top of semiconductor package 401. In the illustrated arrangement, gull-wing lead 405b does not include a leadframe trace having a die mount contact that would provide a direct connection to IC die 402. Instead, gull-wing lead 405b would provide a connection from the PCB to one end of an external component attached at 409b.

FIG. 4B illustrates an example pin configuration for one arrangement of a DC-DC converter. No-lead contact 404a is a voltage supply (Vin) pin that receives the primary input voltage for the converter. No-lead contact 404b is an enable (EN) pin that turns the converter on and off. For example, setting the EN pin would enable the device, while a low voltage would disable the device. No-lead contact 404c is a power good (PG) pin that provides a signal to indicate when device start-up is complete. No-lead 404d is a feedback (FB) pin that provides a feedback input to the device, such as a voltage feedback to an internal control loop. No-lead contact 404e is a ground (GND) pin.

No-lead contacts 404f-h and gull-wing lead contact 405a are coupled together by a common leadframe segment. Gull-wing lead contact 405a is connected to one end of an external (Ext) component, such as an inductor. Gull-wing contact 405b is connected to the other end of the external component and provides an output voltage (Vout) for the device.

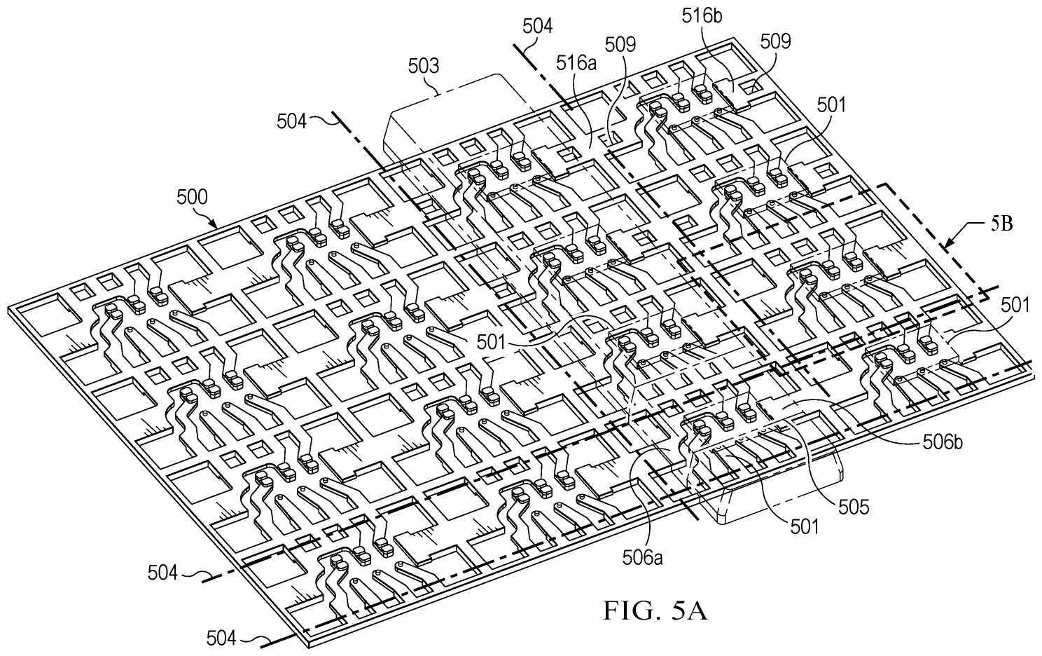

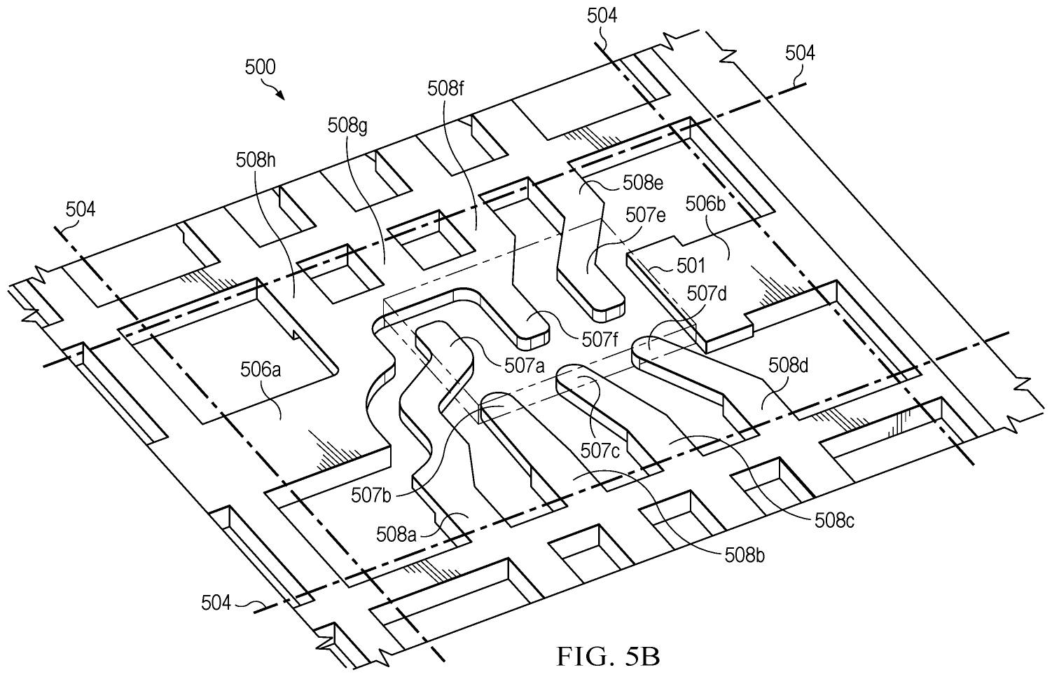

FIG. 5A illustrates a leadframe strip 500 showing an example arrangement of DEN and SOT leads for use with a quad pin out package as described herein. Leadframe strip 500 may be fabricated from a copper sheet that is etched or stamped to form the pattern of lead segments and contacts as shown in FIG. 5A. Various IC dies 501 are shown in phantom to illustrate their position when mounted on the leadframe sheet 500. After the IC dies 501 are mounted, portions of the IC dies 501 and the leadframe strip 500 are encapsulated in a mold compound or encapsulant material 503. The IC dies 501 are spaced from one another by saw streets 504. Saw streets 504 are defined areas of the leadframe strip 500 and the molding compound 504 where groups of integrated circuit devices 501 can be separated in a later process step by cutting through the saw streets 504 to form individual packages 505. Such singulation is typically accomplished via a sawing process. In a conventional mechanical saw process, a saw blade (or dicing blade) is typically advanced along saw streets 504 which extend in prescribed patterns to separate leadframe sections from one another. After separating the individual packages 505, the exposed leadframe segments 506a,b are bent upward into a gull-wing or J-lead shape.

FIG. 5B is a detailed view of a portion of leadframe strip 500 illustrating how IC die 501 is positioned relative to the leadframe elements for attachment. Each IC die 501 is mounted on six contact segments 507a-f. For example, the IC die 501 has six bond pads (not shown) that are aligned with the six contact segments 507a-f during flip-chip mounting. The IC die bond pads may be attached to the contacts by a metal post or bump, such as a copper post. Although the arrangement illustrated in FIG. 5B shows FCOL mounting for IC die 501, in other arrangements, IC die 501 may be mounted using chip-on-lead (COL) technology where the die is mounted on the leadframe with its active surface on top. Wirebonding is then used to connect the die to the leadframe. The die mount contacts 502a-f are attached to lead segments that include no-lead pins 508a-h or leads 506a,b. After the mold compound is applied and the individual packages singulated, then leadframe segments 506a,b are bent upward into a gull-wing or J-lead shape as desired.

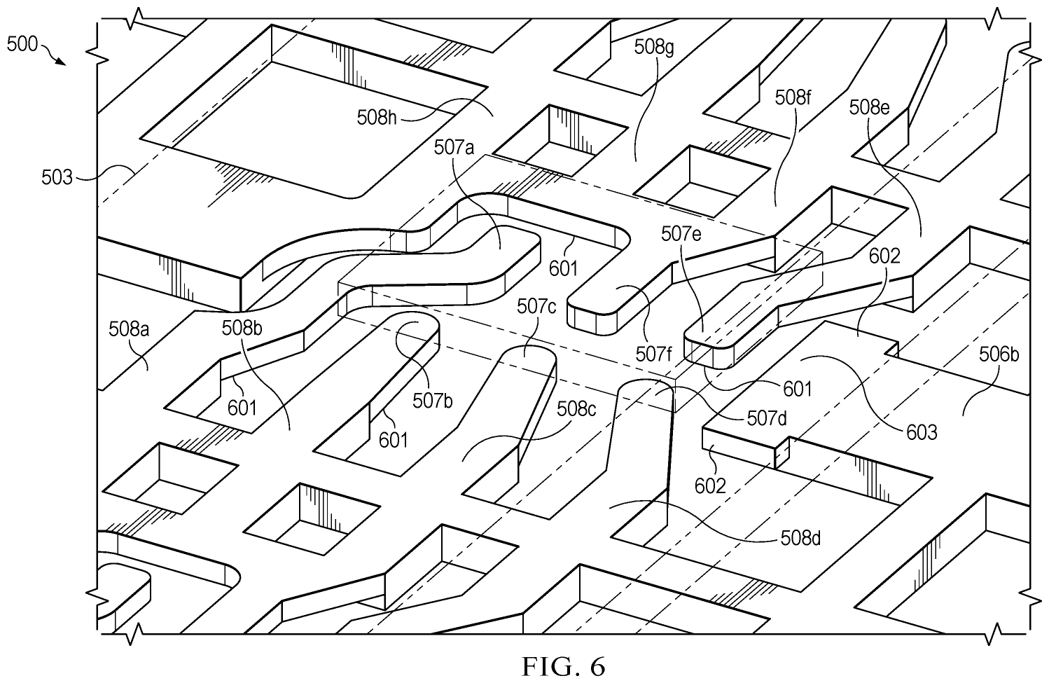

As illustrated in FIG. 6, portions of the leadframe sheet 500 that form the contact segments 507a-f are half-etched on the bottom side 601. When the mold compound 503 is applied, the molding material will cover the IC die 501 and the top and side surfaces of contact segments 507a-f. The mold compound 503 will also flow under the half-etched contact segments 507a-f to cover and protect the bottom 601 the leadframe sheet 500 in those areas. On the other hand, the portions forming no-lead pins 508a-h are not half-etched. As a result, the mold compound 503 will not cover the bottom no-lead pins 508a-h, which will be exposed after singulation for mounting on a PCB or other surface.

A portion of leadframe segment 506b, which forms an end lead after singulation of individual devices, may also be half-etched. Leadframe segment 506b has a two tabs 602 extending laterally from end 603. In one arrangement, at least a portion of end 603 and the tabs 602 are half-etched. This allows the mold compound 503 to flow under a portion of segment 506b. The end 603 is then locked into position by mold compound 503 so that segment 506b can be bent into a gull-wing or J-lead shape after singulation of an individual device.

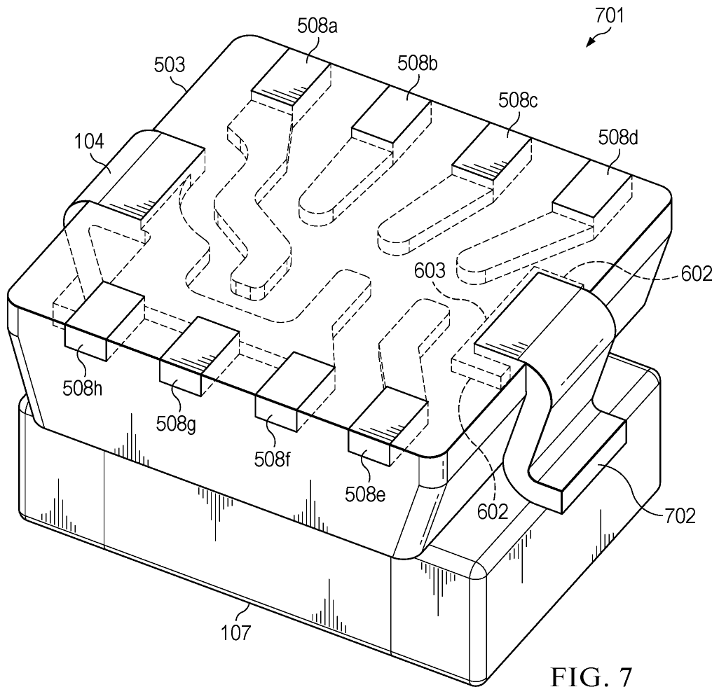

FIG. 7 is a bottom isometric view of a semiconductor package 701 that has been assembled using leadframe sheet 500 as illustrated in FIG. 6. Semiconductor package has a first set of no-lead pins 508a-d on one side and a second set of no-lead pins 508e-h on the opposite side. Gull-wing lead 702 has been formed from leadframe segment 506b. The half-etched tabs 602 on end 603 of segment 506b are enclosed within the mold compound 503. The half-etched tabs 602 on end 603 securely hold lead 702 in place since that lead is not attached to any other internal leadframe structure after singulation.

Referring again to FIG. 5A, an alternative structure for the end leads 506a,b is shown as lead segments 516a,b, which have holes 509. The holes 509 may be formed by etching or stamping the leadframe sheet 500. The holes 509 provide stress relief when the end leads 506a,b are bent into the gull-wing or J-lead shape. Additionally, holes 509 slightly reduce the amount of leadframe material and the overall weight of the semiconductor package.

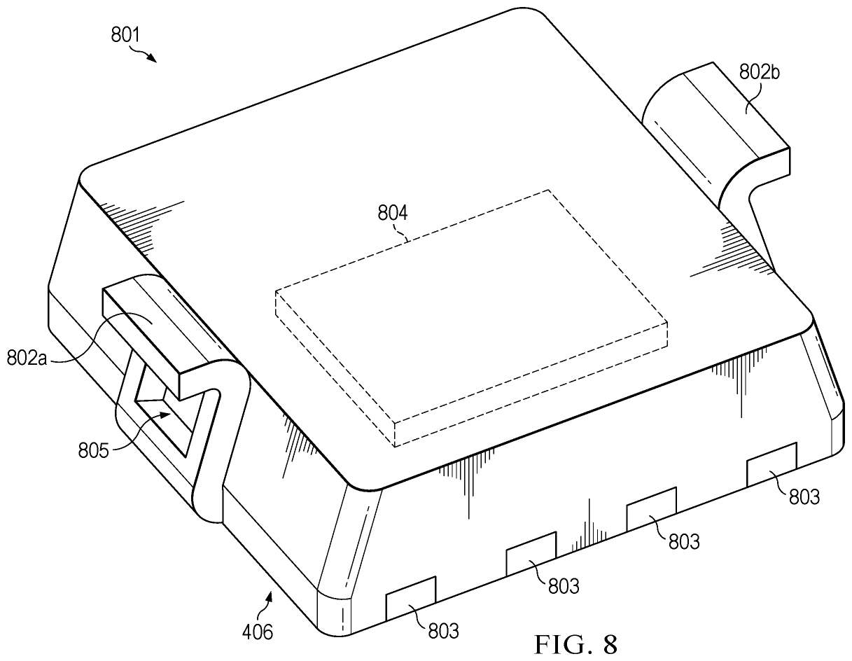

FIG. 8 shows a top isometric view of a semiconductor package 801 having end leads 802a,b with an alternative configuration. Semiconductor package 801 may be assembled from leadframe sheet 500 having holes 509. The end lead 802a and no-lead contacts 803 are internally connected to an IC die 804. The end leads 802a,b are bent into a gull-wing shape after singulation from leadframe sheet 500. In another arrangement, the end leads may instead be bent over the top of semiconductor package 801 to form J-leads. The opening 805 in gull-wing leads 802a,b is formed in the leadframe sheet as hole 509.

An example embodiment of a semiconductor package comprises IC die covered by a mold compound to form a four-sided package with a top surface and a bottom surface. A first group of no-lead contacts are exposed on a first side and on the bottom surface of the package. A second group of no-lead contacts are exposed on a second side and on the bottom surface of the package. The second side is opposite the first side. A first external lead extends from a third side of the package. A second external lead extends from a fourth side of the package opposite the third side. The first and second external leads are bent to extend above the top surface of the package. The first and second external leads may be shaped as gull-wing leads each having a top end that bends away from the package. The first and second external leads may be J-shape leads each having a top end that bends over the top surface of the package. The semiconductor package may further comprise an opening formed in one or more of the first and second external leads.

The first external lead and one or more of the first group of no-lead contacts may be part of a continuous leadframe segment that is attached to the IC die.

The second external lead comprises a half etched end portion within the mold compound. The end portion has half etched tabs that extend laterally from the second external lead and that are not exposed on the bottom surface of the package. The second external lead may not be directly electrically coupled to the IC die in some embodiments.

Each of the no-lead contacts may comprise half etched portions that are not exposed through the mold compound on the bottom surface of the package.

In another arrangement, a semiconductor package comprises a semiconductor die electrically coupled to one or more leadframe segments. An encapsulant covers the semiconductor die and at least a portion of the leadframe segments. The leadframe segments form a first set of no-lead contacts along a first bottom edge of the package. The leadframe segments form a first external lead on a second bottom edge of the package. A second external lead in located on a third bottom edge of the package that is opposite the second edge. The first and second external leads extend above a top surface of the encapsulant. The first and second external leads are shaped as gull-wing leads, wherein the gull-wing leads each have a top end that bends away from the package. Alternatively, the first and second external leads are J-shape leads, wherein the J-shape leads each have a top end that bends over the top surface of the encapsulant. A second set of no-lead contacts are located along a fourth bottom edge of the package opposite the first edge. The semiconductor package may further comprise an electrical device attached to top ends of the first and second external leads above the top surface of the encapsulant.

An opening may be formed in one or more of the first and second external leads. In some configurations, the first external lead is electrically coupled to one or more of the first set of no-lead contacts.

The first external lead and one or more of the first set of no-lead contacts may be part of a continuous leadframe segment.

The second external lead may not be directly electrically coupled to semiconductor die in some configurations.

The second external lead comprises a half etched end portion within the encapsulant. The end portion has half-etched tabs extending laterally from the second external lead and not exposed on a bottom surface of the package.

Each of the first set of no-lead contacts may comprise half etched portions that are not exposed through the encapsulant on a bottom surface of the package.

While various examples of the present disclosure have been described above, it should be understood that they have been presented by way of example only and not limitation. Numerous changes to the disclosed examples can be made in accordance with the disclosure herein without departing from the spirit or scope of the disclosure. Modifications are possible in the described embodiments, and other embodiments are possible, within the scope of the claims. Thus, the breadth and scope of the present invention should not be limited by any of the examples described above. Rather, the scope of the disclosure should be defined in accordance with the following claims and their equivalents.

What is claimed is:

1. A semiconductor package, comprising:
an integrated circuit (IC) die covered by a mold compound to form a four-sided package with a top surface and a bottom surface;
a first group of no-lead contacts exposed on a first side and on the bottom surface of the package;
a second group of no-lead contacts exposed on a second side and on the bottom surface of the package, wherein the second side is opposite the first side;
a first external lead extending from a third side of the package; and
a second external lead extending from a fourth side of the package opposite the third side, the first and second external leads bent to extend above the top surface of the package.

2. The semiconductor package of claim 1, wherein the first and second external leads are shaped as gull-wing leads each having a top end that bends away from the package.

3. The semiconductor package of claim 1, wherein the first and second external leads are J-shape leads each having a top end that bends over the top surface of the package.

4. The semiconductor package of claim 1, further comprising:
an opening formed in one or more of the first and second external leads.

5. The semiconductor package of claim 1, wherein the first external lead and one or more of the first group of no-lead contacts are part of a continuous leadframe segment that is attached to the IC die.

6. The semiconductor package of claim 1, wherein the second external lead comprises:
a half etched end portion within the mold compound, the end portion having half etched tabs that extend laterally from the second external lead and that are not exposed on the bottom surface of the package, and the second external lead is not directly electrically coupled to the IC die.

7. The semiconductor package of claim 1, wherein each of the no-lead contacts comprise half etched portions that are not exposed through the mold compound on the bottom surface of the package.

8. A semiconductor package, comprising:
a semiconductor die electrically coupled to one or more leadframe segments;
an encapsulant covering the semiconductor die and at least a portion of the leadframe segments;
the leadframe segments forming a first set of no-lead contacts along a first bottom edge of the package;
the leadframe segments forming a first external lead on a second bottom edge of the package; and
a second external lead on a third bottom edge of the package opposite the second edge, the first and second external leads extending above a top surface of the encapsulant.

9. The semiconductor package of claim 8, wherein the first and second external leads are shaped as gull-wing leads.

10. The semiconductor package of claim 9, wherein the gull-wing leads each have a top end that bends away from the package.

11. The semiconductor package of claim 8, wherein the first and second external leads are J-shape leads.

12. The semiconductor package of claim 11, wherein the J-shape leads each have a top end that bends over the top surface of the encapsulant.

13. The semiconductor package of claim 8, further comprising:
a second set of no-lead contacts along a fourth bottom edge of the package opposite the first edge.

14. The semiconductor package of claim 8, further comprising:
an opening formed in one or more of the first and second external leads.

15. The semiconductor package of claim 8, wherein the first external lead is electrically coupled to one or more of the first set of no-lead contacts.

16. The semiconductor package of claim 8, wherein the first external lead and one or more of the first set of no-lead contacts are part of a continuous leadframe segment.

17. The semiconductor package of claim 8, wherein the second external lead is not directly electrically coupled to semiconductor die.

18. The semiconductor package of claim 8, wherein the second external lead comprises:
a half etched end portion within the encapsulant, the end portion having half etched tabs extending laterally from the second external lead and not exposed on a bottom surface of the package.

19. The semiconductor package of claim 8, wherein each of the first set of no-lead contacts comprise half etched portions that are not exposed through the encapsulant on a bottom surface of the package.

20. The semiconductor package of claim 8, further comprising:
an electrical device attached to top ends of the first and second external leads above the top surface of the encapsulant.
